(19) United States
(12) Patent Application Publication
(10) Pub. No.: US 2025/0230034 A1
(43) Pub. Date: Jul. 17, 2025

(54) ACCELERATION SENSOR

(71) Applicant: AAC Kaitai Technologies (Wuhan) CO., LTD., Wuhan (CN)

(72) Inventors: Shitao Yan, Wuhan (CN); Zhan Zhan, Wuhan (CN); Lingcheng Kong, Wuhan (CN); Xiao Kan, Wuhan (CN); Zhao Ma, Wuhan (CN); Shan Yang, Wuhan (CN); Yang Li, Wuhan (CN); Kahkeen Lai, Singapore (SG); Qiuyu Tan, Singapore (SG)

(21) Appl. No.: 18/820,315

(22) Filed: Aug. 30, 2024

Related U.S. Application Data
(63) Continuation of application No. PCT/CN2024/072834, filed on Jan. 17, 2024.

(51) Int. Cl. B81B 3/00; G01P 15/125

(52) U.S. Cl. CPC B81B 3/0062; G01P 15/125; B81B 2201/0235; B81B 2203/0136; B81B 2203/0163; B81B 2203/0181; B81B 2203/0307; B81B 2203/04; B81B 2203/056; B81B 2203/058

(57) ABSTRACT

Provided is an acceleration sensor, including a base; a first anchor point fixed to a middle part of the base; an inner side mass unit surrounding an outer side of the first anchor point, an outer side mass unit surrounding an outer side of the inner side mass unit, a first seesaw unit and a second seesaw unit arranged opposite to each other to define an annular structure surrounding an outer side of the outer side mass unit, a first acceleration detection unit and a second acceleration detection unit. Part of the first acceleration detection unit is arranged at the annular structure to detect acceleration in an out-of-plane Z-axis direction, the second acceleration detection unit is arranged at the outer side mass unit to detect acceleration in an in-plane X-axis direction and in an in-plane Y-axis direction. A design thereof is reasonable and the sensitivity is high.

### TECHNICAL FIELD

The present disclosure belongs to the technical field of sensors, and in particular to an acceleration sensor.

### BACKGROUND

An acceleration sensor includes one or more detection weights for detecting acceleration. For example, an acceleration sensor includes a detection weight, and the detection weight is configured to move in a plane to detect acceleration in a plane of the detection weight, and configured to move out of a plane to detect acceleration in a plane perpendicular to the plane of the detection weight. The acceleration may be detected using a capacitive sensor coupled to the detection weight.

Currently, the acceleration sensor has the technical problems of low sensitivity and a low space utilization rate.

### SUMMARY

The present disclosure aims at solving at least one of the technical problems in the related art and provides a new technical solution of an acceleration sensor.

In an aspect, an embodiment of the present disclosure provides an acceleration sensor, including: a base; a first anchor point fixed to a middle part of the base; an inner side coupling unit mass unit and an outer side mass unit, the inner side mass unit surrounding an outer side of the first anchor point and being elastically connected to the first anchor point, and the outer side mass unit surrounding an outer side of the inner side mass unit and being elastically connected to the inner side mass unit; a first seesaw unit and a second seesaw unit, the first seesaw unit and the second seesaw unit being arranged opposite to each other to define an annular structure, and the annular structure surrounding an outer side of the outer side mass unit and being elastically connected to the outer side mass unit; and a first acceleration detection unit and a second acceleration detection unit, at least a part of the first acceleration detection unit being arranged at the annular structure and configured to detect acceleration in an out-of-plane Z-axis direction, the second acceleration detection unit being arranged at the outer side mass unit and configured to detect acceleration in an in-plane X-axis direction and in an in-plane Y-axis direction. The out-of-plane Z-axis direction, the in-plane X-axis direction and the in-plane Y-axis direction are perpendicular to each other.

As an improvement, the acceleration sensor further includes a first elastic member and a second elastic member. An extension direction of the first elastic member is perpendicular to an extension direction of the second elastic member. The inner side mass unit is elastically connected to the first anchor point through the first elastic member, and the outer side mass unit is elastically connected to the inner side mass unit through the second elastic member.

As an improvement, the first elastic member is an X-axis single-degree-of-freedom spring, and the second elastic member is a Y-axis single-degree-of-freedom spring; or the first elastic member is a Y-axis single-degree-of-freedom spring, and the second elastic member is an X-axis single-degree-of-freedom spring.

As an improvement, the X-axis single-degree-of-freedom spring has a serpentine shape and/or has a U-shape, and the Y-axis single-degree-of-freedom spring has a serpentine shape and/or has a U-shape.

As an improvement, the second acceleration detection unit includes an X-axis detection capacitor group and a Y-axis detection capacitor group arranged at the outer side mass unit. The X-axis detection capacitor group is symmetrically arranged about the in-plane X-axis and is also symmetrically arranged about the in-plane Y-axis, and the X-axis detection capacitor group is configured to detect acceleration in the in-plane X-axis direction; and the Y-axis detection capacitor group is symmetrically arranged about the in-plane Y-axis and is also symmetrically arranged about the in-plane X-axis, and the Y-axis detection capacitor group is configured to detect acceleration in the in-plane Y-axis direction.

As an improvement, the X-axis detection capacitor group includes a movable capacitor electrode plate arranged at a side wall of the outer side mass unit, and a first fixed capacitor electrode plate and a second fixed capacitor electrode plate fixed to the base. The first fixed capacitor electrode plate is arranged parallel to and spaced from the second fixed capacitor electrode plate, and each of the first fixed capacitor electrode plate and the second fixed capacitor electrode plate is distributed along the in-plane Y-axis direction. Each of the first fixed capacitor plate and the second fixed capacitor plate is differentially arranged with the movable capacitor plate arranged at the side wall of the outer side mass unit, respectively.

As an improvement, the X-axis detection capacitor group includes a first movable tooth comb capacitor plate arranged at the outer side mass unit and a first fixed tooth comb capacitor plate fixed to the base. The first movable tooth comb capacitor plate and the first fixed tooth comb capacitor plate distributed along the in-plane X-axis direction cooperate to form a first tooth comb capacitor.

As an improvement, the Y-axis detection capacitor group includes a movable electrode arranged at a side wall of the outer side mass unit, and a third fixed capacitor plate and a fourth fixed capacitor plate fixed to the base; and the third fixed capacitor plate is arranged parallel to and spaced from the fourth fixed capacitor plate. Each of the third fixed capacitor plate and the fourth fixed capacitor plate is differentially arranged with the movable capacitor electrode arranged at the side wall of the outer side mass unit, respectively.

As an improvement, the Y-axis detection capacitor group includes a second movable tooth comb capacitor plate disposed on the outer side mass unit and a second fixed tooth comb capacitor plate fixed on the base. The second movable tooth comb capacitor plate distributed along the in-plane Y-axis direction and the second fixed tooth comb capacitor plate are matched to form a second tooth comb capacitor.

As an improvement, the first fixed tooth comb capacitor plate is fixed to the base through a second anchor point; and the second fixed tooth comb capacitor plate is fixed to the base through a third anchor point; and the second anchor point and the third anchor point are both close to the first anchor point.

As an improvement, the first seesaw unit is elastically connected to an end of the outer side mass unit, and the second seesaw unit is elastically connected to another end of the outer side mass unit; each of the first seesaw unit and the second seesaw unit is symmetrically distributed along a symmetry axis of the acceleration sensor; the first seesaw unit includes two first seesaw structures arranged at two sides of the symmetry axis, and the two first seesaw structures rotate about a first rotation axis; the second seesaw unit includes two second seesaw structures arranged at two sides of the symmetry axis, and the two second seesaw structures rotate about a second rotation axis; and each of the first rotation axis and the second rotation axis is distributed along the in-plane Y-axis direction, and the symmetry axis is distributed along the in-plane X-axis direction.

As an improvement, the acceleration sensor further includes a coupling beam. A part of the second seesaw unit is arranged at an outer side of a part of the first seesaw unit to form an embedded structure, the coupling beam is located in the embedded structure, an end of the coupling beam is connected to the first seesaw unit, and another end of the coupling beam is connected to the second seesaw unit.

### BRIEF DESCRIPTION OF DRAWINGS

FIG. 1 is a structural schematic diagram of an acceleration sensor according to embodiment I of the present disclosure;

FIG. 2 is a schematic diagram of an in-plane X-axis detection mode of an acceleration sensor according to embodiment I of the present disclosure;

FIG. 3 is a schematic diagram of an in-plane Y-axis detection mode of an acceleration sensor according to embodiment I of the present disclosure;

FIG. 4 is a schematic diagram of an out-of-plane Z-axis detection mode of an acceleration sensor according to embodiment I of the present disclosure;

FIG. 5 is a schematic diagram of an out-of-plane Z-axis parasitic mode of an acceleration sensor according to embodiment I of the present disclosure;

FIG. 6 is a structural schematic diagram of a coupling beam of an acceleration sensor according to embodiment I of the present disclosure;

FIG. 7 is a structural schematic diagram of an acceleration sensor according to embodiment II of the present disclosure;

FIG. 8 is a schematic diagram of an in-plane X-axis detection mode of an acceleration sensor according to embodiment II of the present disclosure;

FIG. 9 is a schematic diagram of an in-plane Y-axis detection mode of an acceleration sensor according to embodiment II of the present disclosure;

FIG. 10 is a schematic diagram of an out-of-plane Z-axis detection mode of an acceleration sensor according to embodiment II of the present disclosure;

FIG. 11 is a schematic diagram of an out-of-plane Z-axis parasitic mode of an acceleration sensor according to embodiment II of the present disclosure;

FIG. 12 is a structural schematic diagram of a coupling beam of an acceleration sensor according to embodiment II of the present disclosure;

FIG. 13 is a structural schematic diagram of an acceleration sensor according to embodiment III of the present disclosure;

FIG. 14 is a schematic diagram of an in-plane X-axis detection mode of an acceleration sensor according to embodiment III of the present disclosure;

FIG. 15 is a schematic diagram of an in-plane Y-axis detection mode of an acceleration sensor according to embodiment III of the present disclosure;

FIG. 16 is a schematic diagram of an out-of-plane Z-axis detection mode of an acceleration sensor according to embodiment III of the present disclosure;

FIG. 17 is a schematic diagram of an out-of-plane Z-axis parasitic mode of an acceleration sensor according to embodiment III of the present disclosure;

FIG. 18 is a structural schematic diagram of a coupling beam of an acceleration sensor according to embodiment III of the present disclosure;

FIG. 19 is a structural schematic diagram of an X-axis detection capacitor group and a Y-axis detection capacitor group in an acceleration sensor according to embodiment III of the present disclosure;

FIG. 20 is a structural schematic diagram of an X-axis detection capacitor group in an acceleration sensor according to embodiment I and embodiment II of the present disclosure; and

FIG. 21 is a structural schematic diagram of a Y-axis detection capacitor group in an acceleration sensor according to embodiment I and embodiment II of the present disclosure.

In the figures: 100: symmetry axis; 200: first rotation axis; 300: second rotation axis; 1: inner side mass unit; 2: outer side mass unit; 31: first anchor point; 32: second anchor point; 33: third anchor point; 4: first seesaw unit; 5: second seesaw unit; 6: first acceleration detection unit; 71: X-axis detection capacitor group; 711: first through hole; 712: first fixed capacitor plate; 713: second fixed capacitor plate; 714: first fixed tooth comb capacitor plate; 715: first movable tooth comb capacitor plate; 72: Y-axis detection capacitor group; 721: second through hole; 722: third fixed capacitor plate; 723: fourth fixed capacitor plate; 724: second fixed tooth comb capacitor plate; 725: second movable tooth comb capacitor plate; 81: first elastic member; 82: second elastic member; 9: coupling beam; 10: first out-of-plane detection mass; 11: second out-of-plane detection mass.

### DESCRIPTION OF EMBODIMENTS

Various exemplary embodiments of the present disclosure are described in detail with reference to the drawings. It should be noted that: the relative arrangement of components and steps, numeric expressions and values described in the embodiments are not intended to limit the scope of the present disclosure, unless otherwise stated.

Embodiments of the present disclosure will be described in detail below, examples of which are shown in the accompanying drawings, same or similar numerals throughout indicate same or similar elements or elements with same or similar functions. Embodiments described below with reference to the accompanying drawings are illustrative and are only intended to explain the present disclosure shall not be interpreted as limitations on the present disclosure. All other embodiments obtained by those skilled in the art without paying creative labor shall fall into the protection scope of the present disclosure.

The feature defined by “first” and “second” in the specification and claims can indicate or imply to include one or more of the features. In the description of the present disclosure, unless otherwise indicated, “a plurality of” means two or more. In addition, “and/or” in the specification and claims indicates at least one of the associated objects, and the character “/” generally indicates that the associated objects are of an “or” relationship.

In the description of the present disclosure, it should be understood that the terms such as “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential” and the like indicate an orientation or position relationship based on the orientation or position relationship shown in the drawings, and merely for convenience in describing the present disclosure and simplifying the description, and do not indicate or imply that the referred device or element must have a specific orientation, be constructed and operated in a specific orientation, and therefore cannot be understood as a limitation on the present disclosure.

In the description of the present disclosure, it should be noted that, unless otherwise specified and limited, the terms such as “mount”, “connect” and “join” should be understood broadly, for example, it may be a fixed connection, a detachable connection, or an integral connection; it may be a mechanical connection, or an electrical connection; it may be a direct connection, or an indirect connection through an intermediate medium; or it may be an internal communication between two elements. For those of ordinary skill in the art, the specific meanings of the foregoing terms in the present disclosure can be understood on a case-by-case basis.

### Embodiment I

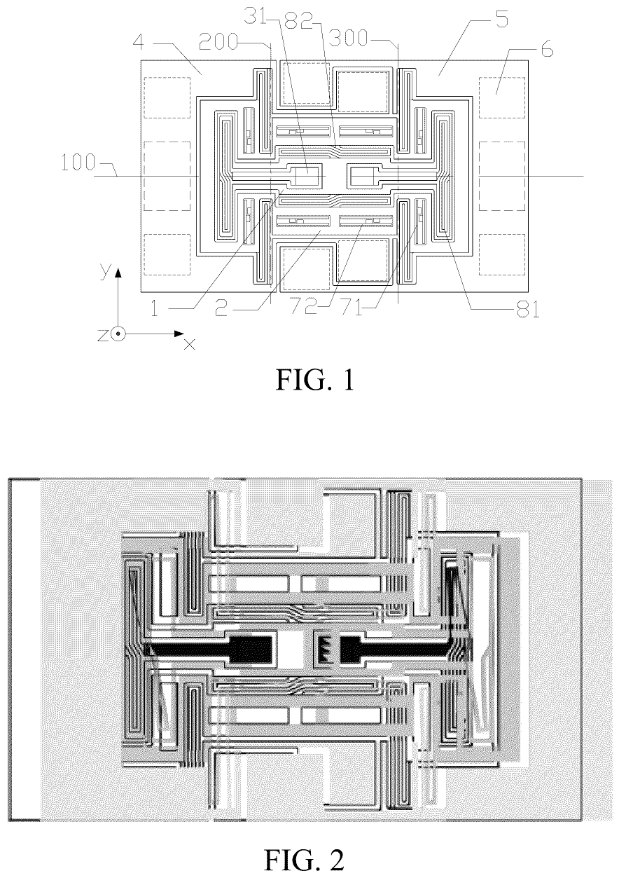

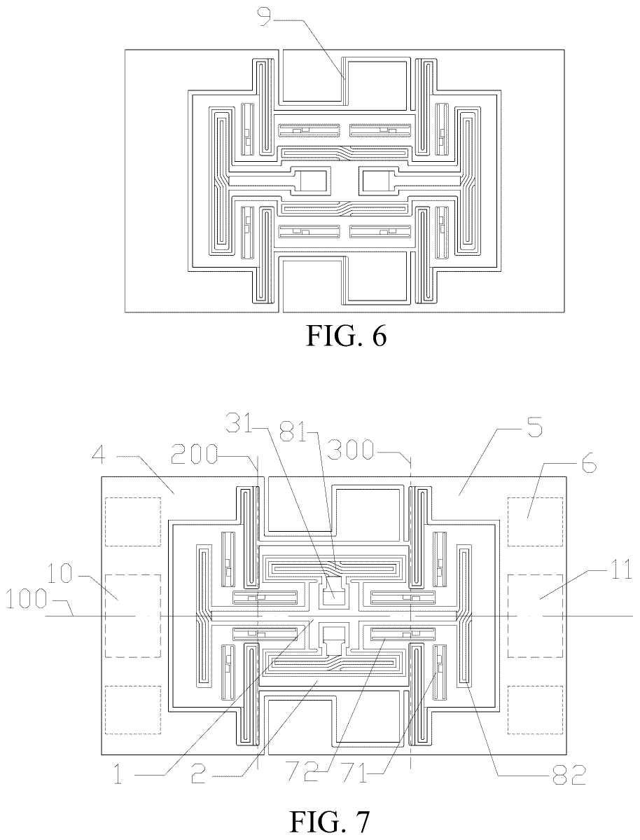

Referring to FIGS. 1-6, in an aspect, an embodiment of the present disclosure provides an acceleration sensor. In order to facilitate description of the acceleration sensor of the present disclosure, an X-Y-Z-axis three-dimensional coordinate system is established, in which an in-plane X-axis direction, an in-plane Y-axis direction and an out-of-plane Z-axis direction are defined, and the in-plane X-axis direction, the in-plane Y-axis direction and the out-of-plane Z-axis direction are perpendicular to each other.

In an example, the acceleration sensor includes a base, a first anchor point 31, an inner side mass unit 1, an outer side mass unit 2, a first seesaw unit 4, a second seesaw unit 5, a first acceleration detection unit 6 and a second acceleration detection unit.

For example, two first anchor points 31 are symmetrically distributed about the in-plane X-axis.

In an example, the first anchor point 31 is fixed to a middle part of the base; the inner side mass unit 1 surrounds an outer side of the first anchor point 31 and is elastically connected to the first anchor point 31, and the outer side mass unit 2 surrounds an outer side of the inner side mass unit 1 and is elastically connected to the inner side mass unit 1. The first seesaw unit 4 and the second seesaw unit 5 are oppositely disposed, and the first seesaw unit 4 and the second seesaw unit 5 enclose an annular structure. The annular structure surrounds an outer side of the outer side mass unit 2 and is elastically connected to the outer side mass unit 2, for example, the annular structure surrounds and is elastically connected to the outer side mass unit 2 by means of a torsion spring. At least part of the first acceleration detection unit 6 is arranged at the annular structure and is configured to detect acceleration in the out-of-plane Z-axis direction. The second acceleration detection unit is arranged at the outer side mass unit 2 and is configured to detect acceleration in the in-plane X-axis direction and in the in-plane Y-axis direction. The out-of-plane Z-axis direction, the in-plane X-axis direction and the in-plane Y-axis direction are perpendicular to each other.

The first acceleration detection unit 6 is configured to detect rotation of the seesaw caused by movement of the detection mass arranged at the annular structure enclosed by the first seesaw unit 4 and the second seesaw unit 5 in the out-of-plane Z-axis direction caused by out-of-plane acceleration, and the second acceleration detection unit is configured to detect translational motion caused by movement of the detection mass arranged at the outer side mass unit 2 in the in-plane X-axis direction and in the in-plane Y-axis direction caused by in-plane acceleration.

In this embodiment of the present disclosure, the acceleration sensor is reasonable in design. The detection mass in the out-of-plane Z-axis direction is arranged at the annular structure, the detection mass in the in-plane X-axis direction at least includes detection mass arranged at the outer side mass unit 2 and detection mass arranged at the annular structure, and the detection mass in the in-plane Y-axis direction at least includes detection mass arranged at the outer side mass unit 2 and detection mass arranged at the annular structure. Such a design having shared detection mass enables the acceleration sensor to have higher space utilization rate, so that the acceleration sensor has higher sensitivity within a same area.

It should be noted that the annular structure enclosed by the first seesaw unit 4 and the second seesaw unit 5 is elastically connected to the outer side mass unit 2, to provide support for linear movement of the detection weight arranged at the annular structure in the in-plane X-axis direction and in the in-plane Y-axis direction. Meanwhile, the outer side mass unit 2 is elastically connected to the inner side mass unit 1, and the inner side mass unit 1 is elastically connected to the first anchor point 31. For example, the outer side mass unit and the inner side mass unit are connected by a second elastic connection member, and the second elastic connection member is parallel to the in-plane Y axis, then the second elastic connection member provides flexible support for the outer side mass unit and the annular structure (that is, the first seesaw unit and the second seesaw unit) to move in the in-plane X axis direction. In this case, the first elastic connection member elastically connected between the inner side mass unit (the mass unit) and the first anchor point is parallel to the in-plane X axis, and the first elastic connection member provides flexible support for the inner side mass unit, the outer side mass unit and the annular structure to move in the in-plane Y axis direction.

For example, the outer side mass unit and the inner side mass unit are connected by a second elastic connection member, and the second elastic connection member is parallel to the in-plane X axis, then the second elastic connection member provides flexible support for the outer side mass unit and the annular structure (that is, the first seesaw unit and the second seesaw unit) to move in the in-plane Y axis direction. In this case, the first elastic connection member elastically connected between the inner side mass unit (the mass unit) and the first anchor point is parallel to the in-plane Y axis, and the first elastic connection member provides flexible support for the inner side mass unit, the outer side mass unit and the annular structure to move in the in-plane X axis direction.

In an example, the acceleration sensor is symmetrically distributed about a symmetry axis 100 thereof, and each of the first seesaw unit 4 and the second seesaw unit 5 is symmetrically distributed about the symmetry axis 100.

In an example, the acceleration sensor further includes a first elastic member 81 and a second elastic member 82. An extension direction of the first elastic member 81 is perpendicular to an extension direction of the second elastic member 82.

The inner side mass unit 1 is elastically connected to the first anchor point 31 through the first elastic member 81; and the outer side mass unit 2 is elastically connected to the inner side mass unit 1 through the second elastic member 82. In this way, the connection relationship among the outer side mass unit 2, the inner side mass unit 1, and the first anchor point 31 is relatively simple, which helps to implement movement of the second acceleration detection unit arranged at the outer side mass unit 2 in the in-plane X-axis direction and in the in-plane Y-axis direction, thereby helping the acceleration sensor to detect acceleration in the in-plane X-axis direction and in the in-plane Y-axis direction.

In this embodiment of the present disclosure, the first anchor point 31 is disposed at a structural center of the acceleration sensor, the inner side mass unit 1, the outer side mass unit 2, and the annular structure enclosed by the first seesaw unit 4 and the second seesaw unit 5 share the first anchor point 31 by means of the first elastic member 81 and the second elastic member 82, so that an overall structure of the acceleration sensor is less affected by factors such as stress, and an anti-interference capability of the acceleration sensor is significantly improved.

In an example, the first elastic member 81 is an X-axis single-degree-of-freedom spring, and the second elastic member 82 is a Y-axis single-degree-of-freedom spring. The detection mass of the anchor point, the outer side mass unit 2, and the detection mass of the inner side mass unit 1 may be configured according to a layout requirement of the base, which is not limited in the present disclosure.

In the above-described implementations, the in-plane X-axis detection mass includes detection mass arranged at the outer side mass unit 2, detection mass arranged at the inner side mass unit 1, and detection mass arranged at the annular structure. The detection mass in the in-plane Y-axis direction includes detection mass arranged at the outer side mass unit 2 and detection mass arranged at the annular structure. Such a design of sharing common detection mass helps further enable the accelerometer to have higher sensitivity and higher space utilization rate within a same area.

In an example, the X-axis single-degree-of-freedom spring is of a serpentine shape; and the Y-axis single-degree-of-freedom spring is of a serpentine shape. The structure design of the X-axis single-degree-of-freedom spring and the Y-axis single-degree-of-freedom spring is reasonable, which helps to implement the movement of the detection mass arranged at the outer side mass unit 2 in the in-plane X-axis direction and in the in-plane Y-axis direction.

In an example, the second acceleration detection unit includes an X-axis detection capacitor group 71 and a Y-axis detection capacitor group 72 that are arranged at the outer side mass unit 2.

The X-axis detection capacitor group 71 is symmetrically arranged about the in-plane X-axis, and is also symmetrically arranged about the in-plane Y-axis. The X-axis detection capacitor group 71 is configured to detect acceleration in the in-plane X-axis direction.

The Y-axis detection capacitor group 72 is symmetrically arranged about the in-plane Y-axis, and is also symmetrically arranged about the in-plane X-axis. The Y-axis detection capacitor group 72 is configured to detect acceleration in the in-plane Y-axis direction.

In the above-described implementations, the second acceleration detection unit has a reasonable structural design, which helps to accurately detect acceleration in the in-plane X-axis direction and in the in-plane Y-axis direction.

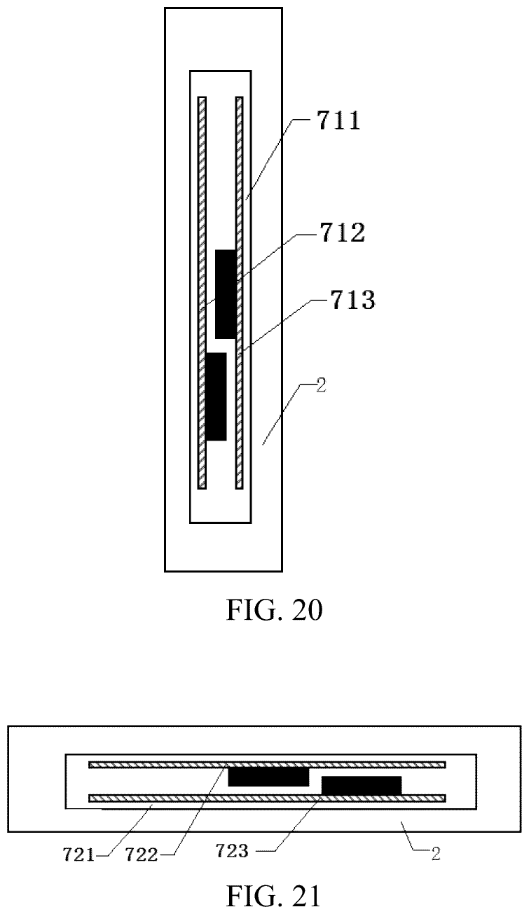

In an example, referring FIG. 20, the X-axis detection capacitor group 71 includes a movable capacitor electrode plate arranged at a side wall of the outer side mass unit, and a first fixed capacitor electrode plate 712 and a second fixed capacitor electrode plate 713 fixed to the base. The first fixed capacitor electrode plate 712 is arranged parallel to and spaced from the second fixed capacitor electrode plate 713, and each of the first fixed capacitor electrode plate 712 and the second fixed capacitor electrode plate 713 is distributed along the in-plane Y-axis direction.

Each of the first fixed capacitor plate 712 and the second fixed capacitor plate 713 is differentially arranged with the movable capacitor plate at the side wall of the outer side mass unit, respectively.

For example, the outer side mass unit 2 is provided with a first through hole 711 extending to the base, the first fixed capacitor plate 712 and the second fixed capacitor plate 713 are both disposed in the first through hole 711, and the movable capacitor plate is disposed at a side wall (that is, a side wall of the first through hole) at a corresponding position of the outer side mass unit.

It should be noted that, when the outer side mass unit 2 is displaced to the left under an action of the left acceleration in the in-plane X-axis direction, the capacitance spacing of the first differential detection capacitor formed by the first capacitor electrode plate 712 and the movable capacitor electrode plate at the side wall of the outer side mass unit 2 is increased, and the capacitance spacing of the second differential detection capacitor formed by the second capacitor electrode plate 713 and the movable capacitor electrode plate at the side wall of the outer side mass unit 2 is decreased. In this case, the first differential detection capacitor and the second differential detection capacitor change in proportion to the left acceleration in the in-plane X-axis direction, and a real-time value of the left acceleration in the in-plane X-axis direction can be obtained by detecting the change of the capacitance difference.

Similarly, when the outer side mass unit 2 is displaced to the right under an action of the right acceleration in the in-plane X-axis, a real-time value of the right acceleration in the in-plane X-axis may also be obtained by detecting the change of the capacitance difference.

In the above-described implementations, the X-axis detection capacitor group 71 has a reasonable structural design, which helps to accurately detect the acceleration in the in-plane X-axis direction.

In an example, referring to FIG. 21, the Y-axis detection capacitor group 72 includes a movable electrode disposed at a side wall of the outer side mass unit, and a third fixed capacitor plate 722 and a fourth fixed capacitor plate 723 that are fixed to the base. The third fixed capacitor plate 722 is arranged parallel to and spaced from the fourth fixed capacitor plate 723.

Each of the third fixed capacitor plate 722 and the fourth fixed capacitor plate 723 is differentially arranged with the movable capacitor electrode arranged at the side wall of the outer side mass unit.

For example, the outer side mass unit 2 is provided with a second through hole 721 extending to the base, the third fixed capacitor plate 722 and the fourth fixed capacitor plate 723 are both disposed in the first through hole 721, and a movable capacitor plate is disposed at a side wall (that is, a side wall of the first through hole) at a corresponding position of the outer side mass unit.

It should be noted that, when the outer side mass unit 2 is displaced upward under an action of the upward acceleration in the in-plane Y-axis direction, the capacitance spacing of the third differential detection capacitor formed by the third capacitor electrode plate 722 and the movable capacitor electrode plate arranged at the side wall of the outer side mass unit 2 is increased, and the capacitance spacing of the fourth differential detection capacitor formed by the fourth capacitor electrode plate 723 and the movable capacitor electrode plate arranged at the side wall of the outer side mass unit 2 is decreased. In this case, the third differential detection capacitor and the fourth differential detection capacitor change in proportion to the upward acceleration in the in-plane Y-axis direction, and a real-time value of the left acceleration in the in-plane Y-axis direction may be obtained by detecting the change of the capacitance difference.

Similarly, when the second detection weight 721 is displaced downward under an action of the downward acceleration in the in-plane Y-axis, a real-time value of the right acceleration along the in-plane Y-axis may also be obtained by detecting the change of the capacitance difference.

In the above-described implementations, the Y-axis detection capacitor group 72 has a reasonable structural design, which helps to accurately detect the acceleration in the in-plane Y-axis direction.

In an example, the first seesaw unit 4 is elastically connected to an end of the outer side mass unit 2, and the second seesaw unit 5 is elastically connected to another end of the outer side mass unit 2. Each of the first seesaw unit 4 and the second seesaw unit 5 is symmetrically distributed about a symmetry axis 100 of the acceleration sensor. The first seesaw unit 4 includes two first seesaw structures arranged at two sides of the symmetry axis 100, and each of the two first seesaw structures rotates about a first rotation axis 200. The second seesaw unit 5 includes two second seesaw structures arranged at two sides of the symmetry axis 100, and each of the two second seesaw structures rotates about a second rotation axis 300. Each of the first rotation axis 200 and the second rotation axis 300 is distributed along the in-plane Y-axis direction. The symmetry axis 100 is distributed along the in-plane X-axis direction.

In the above-mentioned implementations, the first seesaw unit 4 and the second seesaw unit 5 are used as the detection structure for detecting the out-of-plane acceleration, so that the first seesaw unit 4 and the second seesaw unit 5 may rotate reversely about the in-plane Y-axis direction under an action of acceleration in the out-of-plane Z-axis direction, and the out-of-plane acceleration (i.e., the Z-axis acceleration) of the acceleration sensor may be detected by the first acceleration detection unit 6 arranged at the first seesaw unit 4 and the second seesaw unit 5. Meanwhile, when the two first seesaw structures or the two second seesaw structures are subjected to the undesired Y-axis angular acceleration, the two first seesaw structures or the two second seesaw structures rotate towards a same direction, and the capacitance change of the first acceleration detection unit 6 caused by the rotation towards a same direction is offset when the first acceleration detection unit 6 detects, so that the layout of the two first seesaw structures and the two second seesaw structures greatly reduces an influence of the acceleration sensor on the Y-axis angular acceleration, it not only improves the cross inhibition ratio of the acceleration sensor, but also improves the accuracy of the out-of-plane acceleration detection of the acceleration sensor.

In an example, a first groove is provided at an outer side of the first seesaw unit 4, a second groove is provided at an inner side of the second seesaw unit 5. A part of the first seesaw unit 4 is embedded in the second groove, and a part of the second seesaw unit 5 is embedded in the first groove, to form an embedded structure. The embedded structure is located between the first rotation axis 200 and the second rotation axis 300.

In the above-described implementations, an embedded structure is adopted between the first seesaw unit 4 and the second seesaw unit 5. The embedded structure helps to extend the rotating arms of the first seesaw unit 4 and the second seesaw unit 5, and meanwhile, the first acceleration detection unit 6 may be arranged at a region farther from the rotation axis, so that the gain of detection of the out-of-plane acceleration is greater.

In an example, referring to FIG. 7, the acceleration sensor further includes a first out-of-plane detection weight 10 and a second out-of-plane detection weight 11.

Each first seesaw structure includes a first rotating sub-portion and a second rotating sub-portion, the first rotating sub-portion and the second rotating sub-portion are located at two opposite sides of the first rotation axis 200, and a first groove is arranged at an outer side of the second rotating sub-portion. Each second seesaw structure includes a third rotating sub-portion and a fourth rotating sub-portion, the third rotating sub-portion and the fourth rotating sub-portion are located at two opposite sides of the second rotation axis 300, and a second groove is arranged at an inner side of the third rotating sub-portion. A part of the second rotating sub-portion is embedded in the second groove, and a part of the third rotating sub-portion is embedded in the first groove.

The first out-of-plane detection weight 10 is arranged at the first rotating sub-portion, and the second out-of-plane detection weight 11 is arranged at the fourth rotating sub-portion.

In the above-described implementations, the first out-of-plane detection weight 10 forms an asymmetric detection weight of the first seesaw unit, the second out-of-plane detection weight 11 forms an asymmetric detection weight of the second seesaw unit, and each of the first out-of-plane detection weight 10 and the second out-of-plane detection weight 11 is located at a distal end of the seesaw structure, so that the first seesaw structure and the second seesaw structure are more sensitive to external acceleration, thereby improving the gain of detection of the acceleration sensor.

In an example, the first out-of-plane detection weight 10 is disposed at a position where the two first rotating sub-portions are connected, and the second out-of-plane detection weight 11 is disposed at a position where the two fourth rotating sub-portions are connected, thereby further increasing a distance between the detection mass and the rotation axis. In this way, the first seesaw structure and the second seesaw structure are more sensitive to external acceleration, thereby further improving the gain of detection of the acceleration sensor.

In an example, the acceleration sensor further includes a coupling beam 9.

A part of the second seesaw unit 5 is arranged at an outer side of a part of the first seesaw unit 4 to form an embedded structure, and the coupling beam 9 is located in the embedded structure. An end of the coupling beam 9 is connected to the first seesaw unit 4, and another end of the coupling beam 9 is connected to the second seesaw unit 5.

In the above-described implementations, by providing the coupling beam 9 between the first seesaw unit 4 and the second seesaw unit 5, the coupling beam 9 can weaken the rotation of the first seesaw unit 4 and the second seesaw unit 5 towards a same direction, thereby further inhibiting the influence of the y-axis angular acceleration, and help further improving the accuracy of detection of the out-of-plane acceleration by the acceleration sensor.

In an implementation, the coupling beam 9 extends in a direction perpendicular to the symmetry axis 100, an end of the coupling beam 9 is connected to the second rotating sub-portion, and another end of the coupling beam 9 is connected to the third rotating sub-portion.

In an implementation, each of the first rotating sub-portion, the second rotating sub-portion, the third rotating sub-portion, and the fourth rotating sub-portion is provided with a first acceleration detection unit 6. A part of the first acceleration detection unit 6 is located at a position of the first seesaw unit 4 away from the first rotation axis 200, and a part of the first acceleration detection unit 6 is located at a position of the second seesaw unit 5 away from the second rotation axis 300. The plurality of first acceleration detection units 6 are symmetrically distributed about the symmetry axis 100.

For example, the coupling beam 9 has a strip shape, an end of the coupling beam 9 is fixed to a bottom wall of the first groove, and anther end of the coupling beam 9 is fixed to the bottom wall of the second groove. Such a design makes the structure of the coupling beam 9 simple and facilitates the assembly of the acceleration sensor.

In some implementations, the coupling beam 9 includes two sub-beams parallel to each other. An end of the sub-beam is fixed to a bottom wall of the first groove, and another end of the sub-beam is fixed to a bottom wall of the second groove. Such a design further improves the capability of the coupling beam 9 to weaken the rotation of the first seesaw unit 4 and the second seesaw unit 5 towards a same direction, thereby better inhibiting the influence of y-axis angular acceleration.

In some implementations, the coupling beam 9 has a rectangular shape. A middle part of a side of the coupling beam 9 is fixed to an inner side wall of the first groove, and a middle part of another side of the coupling beam 9 is fixed to an inner side wall of the second groove. Such a design makes the structural design of the coupling beam 9 reasonable, and can effectively weaken the rotation of the first seesaw unit 4 and the second seesaw unit 5 towards a same direction.

In an example, the first acceleration detection unit 6 includes a first out-of-plane detection capacitor plate and a second out-of-plane detection capacitor plate, the first out-of-plane detection capacitor plate and the second out-of-plane detection capacitor plate are arranged opposite to each other to form a capacitor plate structure. The first out-of-plane detection capacitor plate is located at the base or a cavity cover, and the second out-of-plane detection capacitor plate is located at the first seesaw unit 4 and the second seesaw unit 5.

In an example, the first acceleration detection unit 6 detects acceleration in the Z-axis direction (that is, the out-of-plane acceleration), so that the first seesaw unit 4 and the second seesaw unit 5 rotate reversely, but in the parasitic mode, the first seesaw unit 4 and the second seesaw unit 5 may rotate towards a same direction about the Y-axis under an action of the Y-axis angular acceleration. In order to weaken the influence of the parasitic mode, the first seesaw unit 4 and the second seesaw unit 5 are connected to the coupling beam 9 to weaken the influence of the parasitic mode, that is, weaken the rotation of the first seesaw unit 4 and the second seesaw unit 5 towards a same direction about the Y-axis, thereby further improving the cross inhibition ratio of the accelerometer and significantly improving the accuracy of detection by the acceleration sensor. The parasitic mode is that the acceleration sensor is subjected to both the acceleration in the out-of-plane Z-axis direction and the Y-axis angular acceleration.

### Embodiment II

An embodiment of the present disclosure provides another acceleration sensor, a structure of which is basically the same as that of embodiment I, and only the different parts are described below.

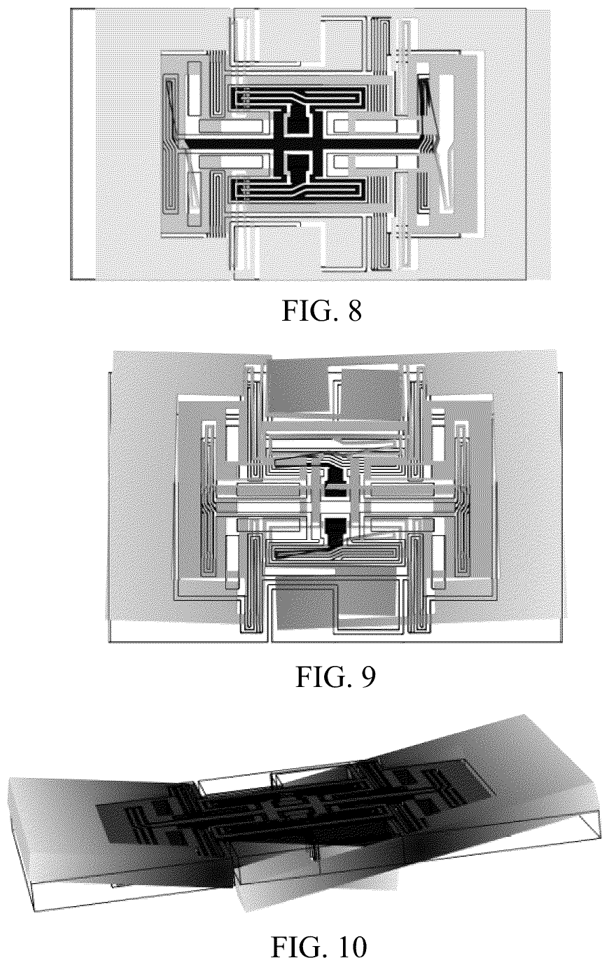

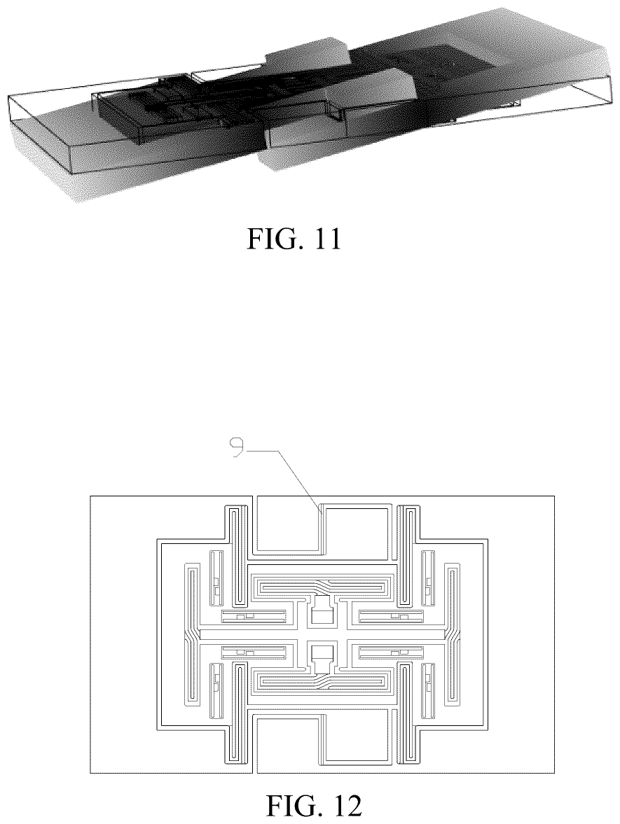

Referring to FIG. 7 to FIG. 12, the first elastic member 81 is a Y-axis single-degree-of-freedom spring, and the second elastic member 82 is an X-axis single-degree-of-freedom spring. The anchor point, the detection mass of the outer side mass unit 2, and the detection mass of the inner side mass unit 1 can be configured according to a layout requirement of the base, which is not limited in the present disclosure.

In the above-described implementations, detection mass in the in-plane Y-axis direction includes detection mass arranged at the outer side mass unit 2, detection mass arranged at the inner side mass unit 1, and detection mass arranged at the annular structure. The detection mass in the in-plane X-axis direction includes detection mass arranged at the outer side mass unit 2 and detection mass arranged at the annular structure. Such a design of sharing common detection mass helps further enable the accelerometer to have higher sensitivity and higher space utilization rate within a same area.

For example, the X-axis single-degree-of-freedom spring and the Y-axis single-degree-of-freedom spring may be designed as different shapes according to a detailed structure of the acceleration sensor, so as to better detect the acceleration in the in-plane Y-axis direction by the acceleration sensor.

In this embodiment, two first anchor points 31 are symmetrically distributed about the symmetry axis 100.

### Embodiment III

An embodiment of the present disclosure provides another acceleration sensor, a structure of which is basically the same as that of embodiment II, and only the different parts are described below.

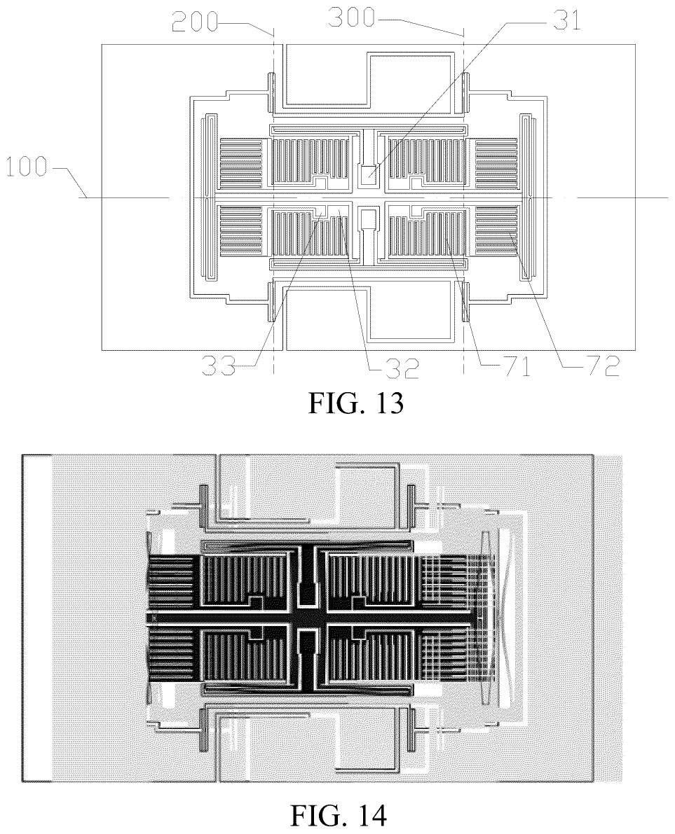

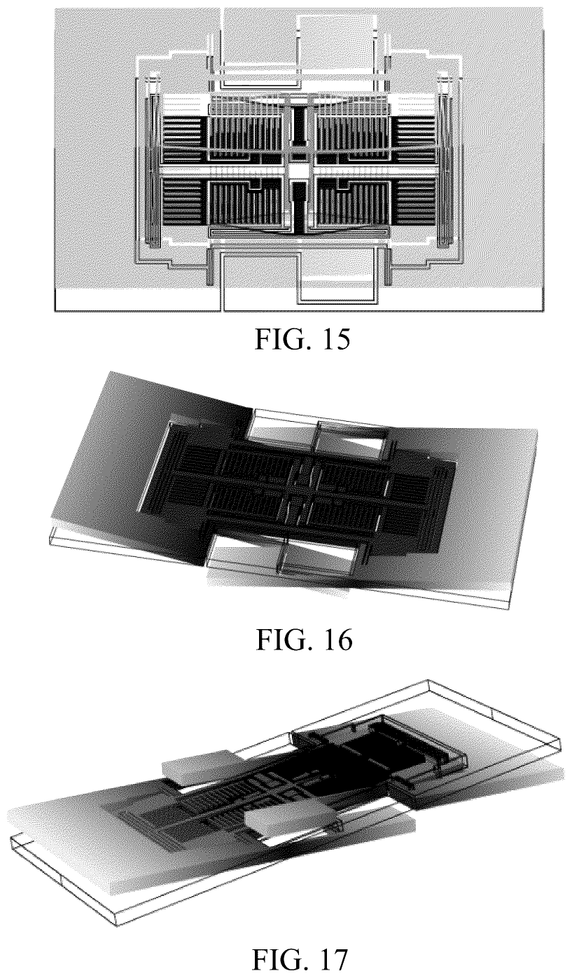

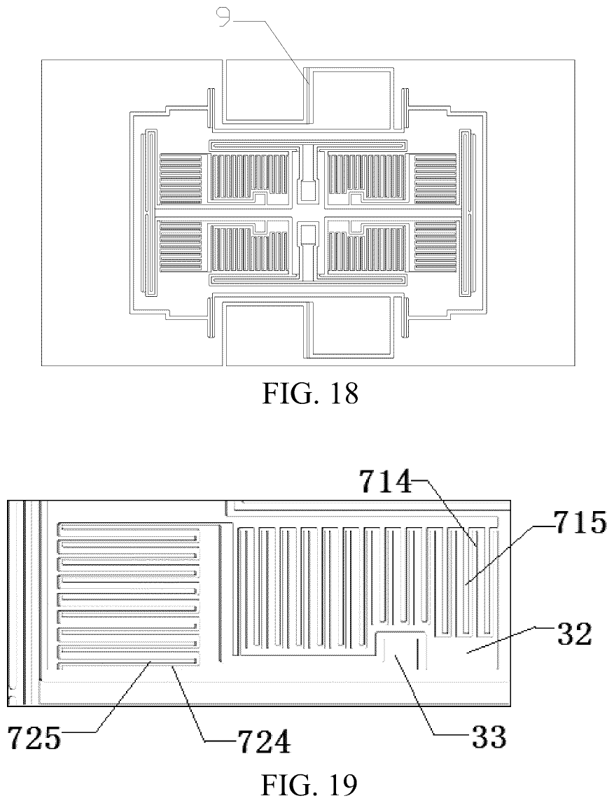

Referring to FIG. 13 to FIG. 18, for example, the X-axis single-degree-of-freedom spring is U-shaped; and the Y-axis single-degree-of-freedom spring is U-shaped.

In the above-described implementations, both the X-axis single-degree-of-freedom spring and the Y-axis single-degree-of-freedom spring are U-shaped. Such a design can weaken cross-coupling caused by asymmetry of the serpentine shape in the in-plane Y-axis detection mode of the acceleration sensor, thereby helping improve detection accuracy of the acceleration sensor.

Referring to FIG. 19, for example, the X-axis detection capacitor group 71 includes a first movable tooth comb capacitor plate 715 arranged at the outer side mass unit 2 and a first fixed tooth comb capacitor plate 714 fixed to the base.

The first movable tooth comb capacitor plate 715 and the first fixed tooth comb capacitor plate 714 distributed along the in-plane X-axis direction cooperate to form a first tooth comb capacitor.

The first fixed tooth comb capacitor plate 714 includes a plurality of capacitor sub-plates arranged in an array along the in-plane X-axis direction. The capacitor sub-plate of the first movable tooth comb capacitor plate 715 is located between two adjacent capacitor sub-plates of the first fixed tooth comb capacitor plate 714.

It should be noted that, when the outer side mass unit 2 is displaced to the left under an action of left acceleration in the in-plane X-axis direction, the capacitance spacing of a fifth differential detection capacitor formed by the capacitor sub-plate of the first movable tooth comb capacitor plate 715 and the capacitor sub-plate of the first fixed tooth comb capacitor plate 714 at a side thereof is reduced, and the capacitance spacing of a sixth differential detection capacitor formed by the capacitor sub-plate of the first movable tooth comb capacitor plate 715 that is located at another side symmetrical about the Y axis and the capacitor sub-plate of the first fixed tooth comb capacitor plate 714 at this side is increased. The fifth differential detection capacitor and the sixth differential detection capacitor change in proportion to the left acceleration in the in-plane X-axis direction, and a real-time value of the left acceleration in the in-plane X-axis direction can be obtained by detecting the change of the capacitance difference.

Similarly, when the outer side mass unit 2 is displaced to the right under an action of right acceleration in the in-plane X-axis, a real-time value of the in-plane right acceleration in the X-axis can be obtained by detecting the change of the capacitance difference.

In an example, the Y-axis detection capacitor group 72 includes a second movable tooth comb capacitor plate 725 arranged at an outer side mass unit 2 and a second fixed tooth comb capacitor plate 724 fixed arranged at the base.

The second movable tooth comb capacitor plate 725 and the second fixed tooth comb capacitor plate 724 distributed along the in-plane Y-axis direction cooperate to form a second tooth comb capacitor.

It should be noted that, when the outer side mass unit 2 is displaced upward under an action of upward acceleration in the in-plane Y-axis direction, the capacitance spacing of a seventh differential detection capacitor formed by the capacitor sub-plate of the second movable tooth comb capacitor plate 725 and the capacitor sub-plate of the second fixed tooth comb capacitor plate 724 at a side thereof is reduced, and the capacitance spacing of an eighth differential detection capacitor formed by the capacitor sub-plate of the second movable tooth comb capacitor plate 725 that is located at another side symmetrical about the X axis and the capacitor sub-plate of the second fixed tooth comb capacitor plate 724 at this side is increased. The seventh differential detection capacitor and the eighth differential detection capacitor have a capacitance difference change proportional to the upward acceleration in the in-plane Y-axis direction, and a real-time value of the upward acceleration in the in-plane Y-axis direction can be obtained by detecting the change of the capacitance difference.

Similarly, when the outer side mass unit 2 is displaced downward under an action of downward acceleration in the in-plane Y-axis, a real-time value of the downward acceleration in the in-plane Y-axis can be obtained by detecting the change of the capacitance difference.

In the above-described implementations, an arrangement manner of the X-axis detection capacitor group 71 and the Y-axis detection capacitor group 72 is changed, so that the arrangement manner of the second acceleration detection unit is more flexible.

In an example, each of a plurality of first fixed tooth comb capacitor plates 714 is fixed to the base through the second anchor point 32; and each of a plurality of second fixed tooth comb capacitor plates 724 is fixed to the base through the third anchor point 33.

Each of the second anchor point 32 and the third anchor point 33 is close to the first anchor point 31.

In the above-described implementations, an arrangement manner of the X-axis detection capacitor group 71 and the Y-axis detection capacitor group 72 is changed, and the second anchor point 32 and the third anchor point 33 used for fixing the X-axis detection capacitor group 71 and the Y-axis detection capacitor group 72 are arranged close to the first anchor point 31 of the motion structure, so that each of the X-axis detection capacitor group 71, the Y-axis detection capacitor group 72 and the first anchor point 31 is located in a structural center of the acceleration sensor, thereby further improving the anti-interference capability of the acceleration sensor, such as stress resistance, and thus helping to ensure the detection accuracy of the acceleration sensor.

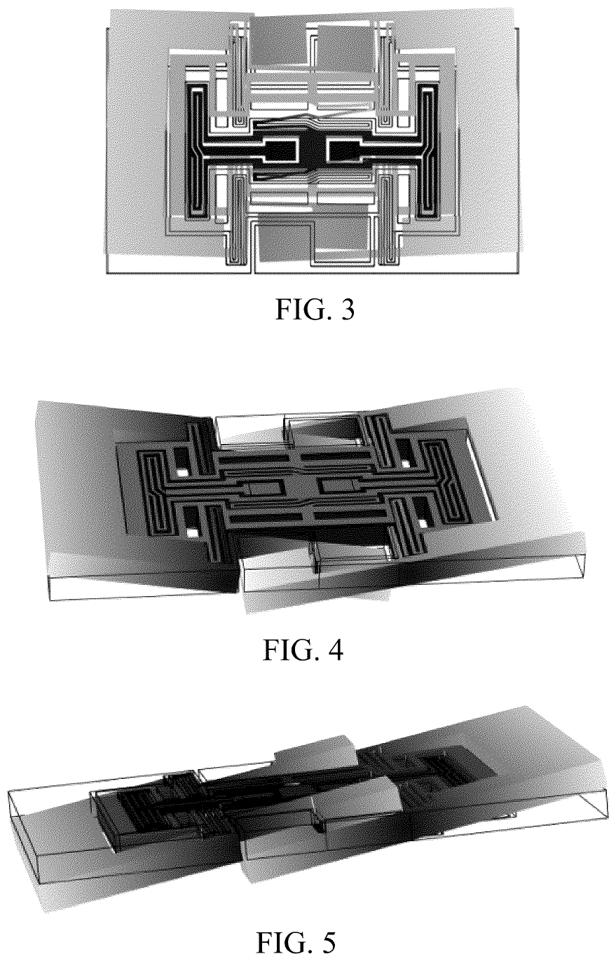

It should be noted that the in-plane X-axis direction detection mode refers to that the acceleration sensor is subjected to acceleration in the in-plane X-axis direction, referring to FIGS. 2, 8 and 14; the in-plane Y-axis direction detection mode refers to that the acceleration sensor is subjected to acceleration in the in-plane Y-axis direction, referring to FIGS. 3, 9 and 15; the out-of-plane Z-axis direction detection mode refers to that the acceleration sensor is subjected to acceleration in the out-of-plane Z-axis direction, referring to FIGS. 4, 10 and 16; and the out-of-plane Z-axis direction parasitic mode refers to that the acceleration sensor is subjected to the acceleration in the out-of-plane Z-axis direction and the Y-axis angular acceleration, referring to FIGS. 5, 11 and 17.

It can be understood that the above-described implementations are merely exemplary implementations used for illustrating the principles of the embodiments of the present disclosure, but the present disclosure is not limited thereto. For those skilled in the art, various modifications and improvements may be made without departing from the essence of the present disclosure, and these modifications and improvements shall fall within a protection scope of the present disclosure.

What is claimed is:

1. An acceleration sensor, comprising:
a base;
a first anchor point fixed to a middle part of the base;
an inner side coupling unit mass unit and an outer side mass unit, wherein the inner side mass unit surrounds an outer side of the first anchor point and is elastically connected to the first anchor point, and the outer side mass unit surrounds an outer side of the inner side mass unit and is elastically connected to the inner side mass unit;
a first seesaw unit and a second seesaw unit, wherein the first seesaw unit and the second seesaw unit are arranged opposite to each other to define an annular structure, and the annular structure surrounds an outer side of the outer side mass unit and is elastically connected to the outer side mass unit; and
a first acceleration detection unit and a second acceleration detection unit, wherein at least a part of the first acceleration detection unit is arranged at the annular structure and configured to detect acceleration in an out-of-plane Z-axis direction, the second acceleration detection unit is arranged at the outer side mass unit and configured to detect acceleration in an in-plane X-axis direction and in an in-plane Y-axis direction,
wherein the out-of-plane Z-axis direction, the in-plane X-axis direction and the in-plane Y-axis direction are perpendicular to each other.

2. The acceleration sensor as described in claim 1, further comprising a first elastic member and a second elastic member;
wherein an extension direction of the first elastic member is perpendicular to an extension direction of the second elastic member; and
wherein the inner side mass unit is elastically connected to the first anchor point through the first elastic member, and the outer side mass unit is elastically connected to the inner side mass unit through the second elastic member.

3. The acceleration sensor as described in claim 2,
wherein the first elastic member is an X-axis single-degree-of-freedom spring, and the second elastic member is a Y-axis single-degree-of-freedom spring; or the first elastic member is a Y-axis single-degree-of-freedom spring, and the second elastic member is an X-axis single-degree-of-freedom spring.

4. The acceleration sensor as described in claim 3,
wherein the X-axis single-degree-of-freedom spring has a serpentine shape and/or has a U-shape, and the Y-axis single-degree-of-freedom spring has a serpentine shape and/or has a U-shape.

5. The acceleration sensor as described in claim 3,
wherein the second acceleration detection unit comprises an X-axis detection capacitor group and a Y-axis detection capacitor group arranged at the outer side mass unit;
wherein the X-axis detection capacitor group is symmetrically arranged about the in-plane X-axis and is also symmetrically arranged about the in-plane Y-axis, and the X-axis detection capacitor group is configured to detect acceleration in the in-plane X-axis direction; and the Y-axis detection capacitor group is symmetrically arranged about the in-plane Y-axis and is also symmetrically arranged about the in-plane X-axis, and the Y-axis detection capacitor group is configured to detect acceleration in the in-plane Y-axis direction.

6. The acceleration sensor as described in claim 5,
wherein the X-axis detection capacitor group comprises a movable capacitor electrode plate arranged at a side wall of the outer side mass unit, and a first fixed capacitor electrode plate and a second fixed capacitor electrode plate fixed to the base, wherein the first fixed capacitor electrode plate is arranged parallel to and spaced from the second fixed capacitor electrode plate, and each of the first fixed capacitor electrode plate and the second fixed capacitor electrode plate is distributed along the in-plane Y-axis direction; and
wherein each of the first fixed capacitor plate and the second fixed capacitor plate is differentially arranged with the movable capacitor plate arranged at the side wall of the outer side mass unit, respectively.

7. The acceleration sensor as described in claim 5,
wherein the X-axis detection capacitor group comprises a first movable tooth comb capacitor plate arranged at the outer side mass unit and a first fixed tooth comb capacitor plate fixed to the base; and
wherein the first movable tooth comb capacitor plate and the first fixed tooth comb capacitor plate distributed along the in-plane X-axis direction cooperate to form a first tooth comb capacitor.

8. The acceleration sensor as described in claim 6,
wherein the Y-axis detection capacitor group comprises a movable electrode arranged at a side wall of the outer side mass unit, and a third fixed capacitor plate and a fourth fixed capacitor plate fixed to the base; and the third fixed capacitor plate is arranged parallel to and spaced from the fourth fixed capacitor plate; and
wherein each of the third fixed capacitor plate and the fourth fixed capacitor plate is differentially arranged with the movable capacitor electrode arranged at the side wall of the outer side mass unit, respectively.

9. The acceleration sensor as described in claim 7, wherein the Y-axis detection capacitor group comprises a second movable tooth comb capacitor plate disposed on the outer side mass unit and a second fixed tooth comb capacitor plate fixed on the base;
the second movable tooth comb capacitor plate distributed along the in-plane Y-axis direction and the second fixed tooth comb capacitor plate are matched to form a second tooth comb capacitor.

10. The acceleration sensor as described in claim 9, wherein the first fixed tooth comb capacitor plate is fixed to the base through a second anchor point; and the second fixed tooth comb capacitor plate is fixed to the base through a third anchor point; and the second anchor point and the third anchor point are both close to the first anchor point.

11. The acceleration sensor as described in claim 1, wherein the first seesaw unit is elastically connected to an end of the outer side mass unit, and the second seesaw unit is elastically connected to another end of the outer side mass unit; each of the first seesaw unit and the second seesaw unit is symmetrically distributed along a symmetry axis of the acceleration sensor; the first seesaw unit comprises two first seesaw structures arranged at two sides of the symmetry axis, and the two first seesaw structures rotate about a first rotation axis; the second seesaw unit comprises two second seesaw structures arranged at two sides of the symmetry axis, and the two second seesaw structures rotate about a second rotation axis; and each of the first rotation axis and the second rotation axis is distributed along the in-plane Y-axis direction, and the symmetry axis is distributed along the in-plane X-axis direction.

12. The acceleration sensor as described in claim 1, further comprising a coupling beam;
wherein a part of the second seesaw unit is arranged at an outer side of a part of the first seesaw unit to form an embedded structure, the coupling beam is located in the embedded structure, an end of the coupling beam is connected to the first seesaw unit, and another end of the coupling beam is connected to the second seesaw unit.
